(19) United States
(12) Patent Application Publication
(10) Pub. No.: US 2024/0263297 A1
(43) Pub. Date: Aug. 8, 2024

(54) LASER INDUCED IONIZATION OF INERT AND REACTIVE GASSES FOR MAGNETRON SPUTTERING

(71) Applicant: Arizona Thin Film Research, LLC, Tucson, AZ (US)

(72) Inventor: Patrick Morse, Tucson, AZ (US)

(73) Assignee: Arizona Thin Film Research, LLC, Tucson, AZ (US)

(21) Appl. No.: 18/436,260

(22) Filed: Feb. 8, 2024

Related U.S. Application Data
(60) Provisional application No. 63/444,119, filed on Feb. 8, 2023.

(51) Int. Cl. C23C 14/34; C23C 14/54

(52) U.S. Cl. CPC C23C 14/3442; C23C 14/54

(57) ABSTRACT

The present disclosure provides a sputtering process comprising the steps of ionizing a process gas with a laser to form an ionized process gas and accelerating the ionized process gas into a target material surface using an electric field generated by at least one electrode.

### CROSS REFERENCE TO RELATED APPLICATION

This Patent Application claims priority under 35 U.S.C. § 119(e) to U.S. Provisional Patent Application No. 63/444,119, entitled “Laser Induced Ionization of Inert and Reactive Gasses for Magnetron Sputtering,” filed Feb. 8, 2023.

### BACKGROUND

The current state of art for magnetron sputtering relies on magnetic confinement of electrons to ionize inert and reactive gasses. When ions are produced within a magnetic confinement, electrons are released in the ionization process and together with other electrons within the magnetic confinement ionize more gas to form a steady state plasma and ionization process. The ions produced in the magnetic confinement are pulled into the target material surface where they can produce sputtered atoms and secondary electrons based on the surface conditions and voltage of the target material surface. The secondary electrons are also used to ionize more gas within the magnetic confinement. This reliance on the secondary electron emission of the target material surface and the electron emission from ionization requires manipulation of the magnetic confinement and the electric fields created between the target material surface and the corresponding anode surfaces to control the ionization rate anywhere within the magnetic confinement to optimize the deposition uniformity and/or the target material utilization. The electron drift created by the Lorentz force acting upon the electrons necessitate the use of a fully closed magnetic racetrack to minimize the plasma impedance and reduce electron loss from the magnetic confinement. The strength of the magnetic field and process gas pressure helps determine the ionization efficiency of the electrons within the magnetic field but ultimately, the plasma impedance is determined by the sputter yield and secondary electron emission of the target material surface.

A power supply is connected to the target material and the voltage that the power supply can maintain is a function of ionization efficiency, the sputter yield, and the secondary electron emission of the target material. Higher ionization efficiency produced by higher gas pressures and or stronger magnetic confinement results in lower sputtering voltages and vice versa. Higher secondary electron emissions also result in lower sputtering voltages and vice versa. Ultimately the sputtering voltage is a finely tuned control between the process gas pressures, cathode material sputter yield, secondary electron emission of the cathode material based on the intrinsic material properties of the target material and any surface reactions taking place in the vacuum chamber, the strength of the magnetic confinement, the strength of the electric fields between the cathode surface and any corresponding anode surfaces, and any variations of any of these variables that may take place at any point along the entire target material surface. The sputter rate anywhere along the magnetic confinement is also a product of these variables and thus, the target to substrate distance needs to be sufficiently long enough to average out any local variations in the sputter rate. The target to substrate distance for magnetically confined plasmas typically ranges from around 75 mm to 150 mm.

For large area sputtering the target material surface is elongated along an axis, typically perpendicular to the axis of travel of the substrate, to enable uniform deposition across the substrate deposition zone. The elongated target material surface needs to extend past the edges of the deposition zone for the substrate to enable the room for the turnaround region of the magnetic confinement and the corresponding electron density gradients that occur in this region when the electrons enter and often exit the magnetic confinement from this region, losing hall current density, and then build up again once the remaining electrons have passed through the turnaround. These extended regions past the substrate deposition zone produce most of the condensate losses for large area sputtering processes and reduces the target material utilization efficiency due to uneven erosion of the turnaround region in comparison to the straight away sections. For large area planar, flat plate, sputtering sources the relationship between the target material length to the area of uniform deposition is roughly the substrate coating length plus two times the target to substrate distance calculated using the thickness of the target material at the end of its useful life. For large area rotary targets, consisting of a target material cladding on the outside of a backing tube that rotates around fixed permanent magnets, the length of the target assembly with the shortest possible backing tube is roughly the length of the required uniform deposition area plus about four times the distance from the fully utilized target surface to the surface of the substrate.

The first sputtering processes developed were not magnetically confined and consisted of a process called diode sputtering. In diode sputtering the voltage of the cathode was increased in a low-pressure environment until plasma would form on the cathode surface. This process had to be conducted at pressures high enough to initiate sufficient ion production to sputter the cathode surface. The higher pressures of this process often produced lower density films due to gas phase collisions from the relatively low mean free path in comparison to the significantly lower pressures utilized for magnetically confined sputtering process.

Planar, rotary, and diode sputtering all suffer from a variety of weaknesses. Target utilization for magnetically confined sputtering processes tops out to around 85% when rotary target materials are used. Planar target material utilization is quite a bit worse and typically tops out around 45-50% depending on the design of the magnetic confinement and target material geometry. The operating voltage of magnetically confined sputtering processes is dictated by the strength of the magnetic field and the secondary electron emission of the target material. The sputtering voltage typically operates in a region low enough that the sputter yield per incident ion is typically less than 1 atom per ion. The low sputter yield at the typical operating sputter voltages leads to 80-85% of the total energy put into sputtering process turning directly into heat in the target material.

In diode sputtering the sustained sputtering voltages are a function of the gas pressure around the target material and when higher voltages are sustained for the sputtering process the amount of energy converted into heat can be reduced per sputtered particle as the sputter yield increases above 1 atom per ion. In current state of the art sputtering processes except for ion beam sputtering, the angle of incidence of the ion arriving at the target material surface is near 0 degrees. With ion beam sputtering the production and acceleration of ions is separated from the sputtering process that takes place at the surface of the target material. This enables another variable to increase the sputter yield as changing the angle of incidence from around 0 to anywhere from about 50 to about 85 degrees can increase the sputter yield by a factor of 3 or more for the same ion energy. While ion beam sputtering has some advantages over magnetically confined sputtering and diode sputtering there is no easy way to create large enough quantities of ions to get the sputtering rates up high enough to compete with the rates of magnetically confined sputtering.

With the limitations of the existing state of the art sputtering processes there is a need for a way to control where and how many ions are produce in proximity to the target material surface allowing for control of the sputtering voltage, ion flux density along the target material surface, and arriving ion angle of incidence to maximize the sputter flux while minimizing the power lost to target material heating.

### SUMMARY

The present disclosure provides a sputtering process comprising the steps of ionizing a process gas (inert and/or reactive gases) with a laser to form an ionized process gas and accelerating the ionized process gas into a target material surface using an electric field generated by at least one electrode. In accordance with various aspects of the present disclosure, if the target material surface is electrically insulating, the target material surface is not necessarily one of the electrodes used to accelerate the ionized process gas. Conversely, if the target material is electrically conductive it can be one of the electrodes used to accelerate the ionized process gas. Additionally, in some embodiments, a wavelength, power, focus, pulse width and duty cycle of the laser is varied to control the number of ions produced within an ionization zone and/or to control an ionization level of ions produced within the ionization zone.

In accordance with various aspects of the present disclosure, independent control of an average kinetic energy of ions arriving at the target material surface and an ion flux arriving at the target material surface are used to optimize a sputter rate efficiency.

In accordance with various aspects of the present disclosure, a process gas pressure within an ionization cross-section of the laser limits the number of ions produced by ionization.

In accordance with various aspects of the present disclosure, the sputtering process may further comprise multiple laser beams configured to converge to produce a plasma activation spot, though alternatively, a single laser is used to create a line of plasma activation. In accordance with various aspects of the present disclosure, the laser is scanned relative to the target material surface to maximize target erosion.

In accordance with various aspects of the present disclosure, a laser ionization zone is scanned relative to the target surface to control coating uniformity on the target material surface.

In accordance with various aspects of the present disclosure, multiple lasers are used to sputter multiple target material surfaces or a single target material surface.

In accordance with various aspects of the present disclosure, the ionized process gas is created in a position relative to the target material surface such that the average kinetic energy of the ionized gas arriving at the target surface optimizes the sputter yield. In accordance with various aspects of the present disclosure, the ionized process gas is created in a position relative to the target material surface such that an angle of incidence of the ionized process gas arriving at the target surface optimizes a sputter yield. In accordance with various aspects of the present disclosure, electrons created by the ionizing and the sputtering process are extracted from the sputtering process by the electric field.

### BRIEF DESCRIPTION OF THE DRAWINGS

The accompanying drawings are included to provide a further understanding of the disclosure and are incorporated in and constitute a part of this specification, illustrate embodiments of the disclosure, and together with the description serve to explain the principles of the disclosure, wherein:

FIG. 1 is a prior art cross sectional view of a planar target based magnetically confined sputtering process.

FIG. 2 is an embodiment of a laser based sputtering process as shown from a cross section normal to the long axis of the target material in accordance with the present disclosure.

FIG. 3 is an embodiment of a single laser beam based sputtering process as shown from a cross section of a vacuum chamber parallel to and above the substrate looking down at the substrate and the laser based sputtering process below the substrate in accordance with the present disclosure.

FIG. 4 is an embodiment of a multiple laser beam based sputtering process as shown from a cross section of a vacuum chamber parallel to and above the substrate looking down at the substrate and the laser based sputtering process below the substrate in accordance with the present disclosure.

### DETAILED DESCRIPTION OF THE ILLUSTRATED EMBODIMENTS

Persons skilled in the art will readily appreciate that various aspects of the present disclosure can be realized by any number of methods and systems configured to perform the intended functions. Stated differently, other methods and systems can be incorporated herein to perform the intended functions. It should also be noted that the accompanying drawing figures referred to herein are not all drawn to scale but may be exaggerated to illustrate various aspects of the present disclosure, and in that regard, the drawing figures should not be construed as limiting. Finally, although the present disclosure can be described in connection with various principles and beliefs, the present disclosure should not be bound by theory.

In general, the present disclosure provides systems and methods for ionizing a process gas with a laser to form an ionized process gas and accelerating the ionized process gas into a target material surface using an electric field generated by at least one actively controlled electrode.

To eliminate the process limitations, complexity of control, and target material geometry constraints required by current stat of the art sputtering processes the current invention separates the sputtering gas ionization process from the ion acceleration process. Ionization of the process gas is achieved with a laser beam adjacent to the surface of the target material and the ions are accelerated toward the target material using an electric field. Controlling where the ions are produced in relation to the target material, the number of ions produced anywhere across the useful area of the target material, and the strength of the electric field used to accelerate the ions separately from material properties of the cathode enables the electric field to be shaped and set to values that can maximize the sputter yield of the cathode material without the secondary electron emission of the material to dominating the control of the plasma impedance. This means that ions produced by the laser can be utilized at optimal efficiency which can maximize the sputter yield per unit of energy required to run the sputtering process.

Elimination of the magnetic confinement also eliminates the reliance of the process on the Lorentz forces produced on the electrons and thus eliminates the need for finely tuned control of the anode surface. When a plasma starts in a magnetically confined sputtering process, the target impedance is at its highest until the hall current in the magnetic confinement has reached a value that will produce enough ions to drop the plasma impedance. The change in the plasma impedance over time leads to increased substrate heating when the plasma is constantly stopped and started again at high frequencies which is required for many materials with lower electrical conductivity. Separating out the ion production enables pulsed processes for lower conductivity cathode materials to operate at a much wider range of voltages that will enable tuning of the processes to achieve lower thermal transfer to the substrates.

Laser induced ionization of the process gasses adjacent to the target material surface can be done with one or more lasers to produce one or more ionization regions per cathode. The distance and angle between the ion production zone and the target material surface to be sputtered can be tuned to optimize the ion energy and angle of incidence as a function of the desired cathode voltage. Higher voltages will accelerate the ions faster and thus lower distances from the ionization regions and the cathode surfaces could be utilized and lower cathode voltages could be used in conjunction with further distances to increase the ion acceleration time and subsequent kinetic energy.

The ion production efficiency is dependent on the pressure of the gas species within the ion production region, the absorption cross section of the gas species, the wavelength of the laser, the cross section of the laser beam, and the beam power density along the length of the beam. To ensure relatively even ion production along the length of the laser beam and the corresponding length of the cathode material techniques such as focal point focusing, frequency sweeping, and combining the energy of multiple intersecting beams can be utilized in addition to other alternative processes, now known or as of yet unknown.

In light of the above, in general, the present disclosure provides a sputtering process comprising the steps of ionizing a process gas with a laser to form an ionized process gas and accelerating the ionized process gas into a target material surface using an electric field generated by at least one actively controlled electrode. Additionally, in some embodiments, a wavelength, power, focus, pulse width and duty cycle of the laser is varied to control the number of ions produced within an ionization zone and/or to control an ionization level of ions produced within the ionization zone.

In accordance with various aspects of the present disclosure, independent control of an average kinetic energy of ions arriving at the target material surface and an ion flux arriving at the target material surface are used to optimize a sputter rate efficiency.

In accordance with various aspects of the present disclosure, an ionized process gas pressure within an ionization cross-section of the laser limits the number of ions produced by ionization.

In accordance with various aspects of the present disclosure, the sputtering process may further comprise multiple laser beams configured to converge to produce a plasma activation spot, though alternatively, a single laser is used to create a line of plasma activation. In accordance with various aspects of the present disclosure, the laser is scanned relative to the target material surface to maximize target erosion.

In accordance with various aspects of the present disclosure, a laser ionization zone is scanned relative to the target surface to control coating uniformity on the target material surface.

In accordance with various aspects of the present disclosure, multiple lasers are used to sputter multiple target material surfaces or a single target material surface.

In accordance with various aspects of the present disclosure, the ionized process gas is created in a position relative to the target material surface such that the average kinetic energy of the ionized gas arriving at the target surface optimizes the sputter yield. In accordance with various aspects of the present disclosure, the ionized process gas is created in a position relative to the target material surface such that an angle of incidence of the ionized process gas arriving at the target surface optimizes a sputter yield. In accordance with various aspects of the present disclosure, electrons created by the ionizing and the sputtering process are extracted from the sputtering process by the electric field.

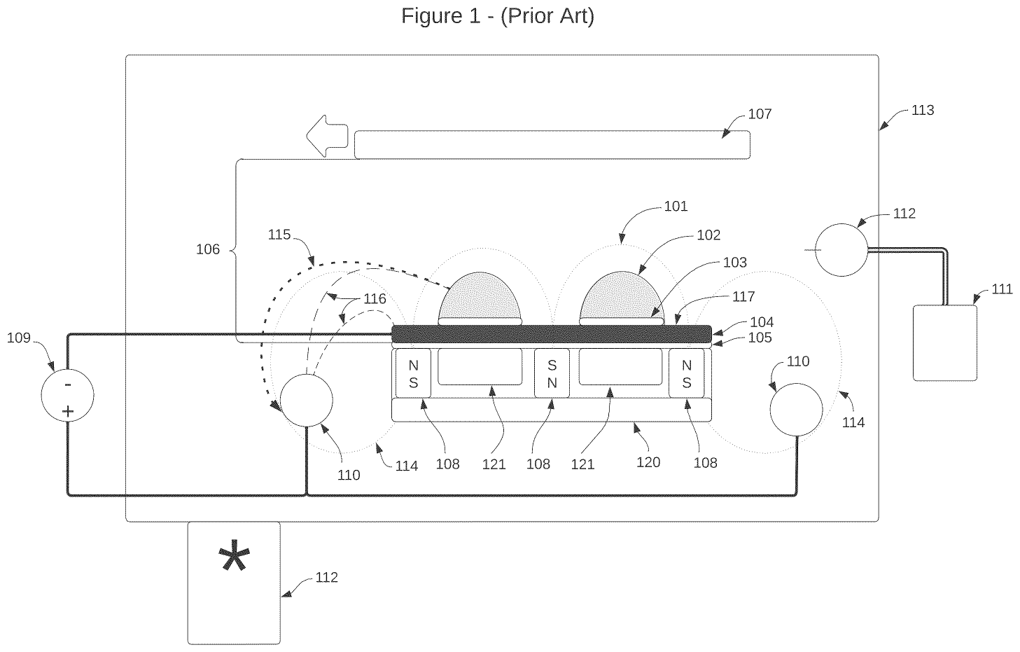

Thus, by way of background, FIG. 1 shows a prior art example of a magnetically confined sputtering processes used to sputter an array of planar and rotary target materials onto a variety of substrates ranging in size and shape from tiny optical filters to gigantic telescope mirrors. In all cases, the magnetic confinement operates the same way independent of target material shape and or size.

In this regard, FIG. 1 depicts a cross section of a planar magnetron sputtering process in a vacuum chamber 113 that is pumped with a high vacuum pump 111 and used to coat a substrate 107 that is traveling from right to left past the planar magnetron that extends into and out of the figure cross-sectional plane further than the substrate 107 by at least two times the target to substrate distance 106 to enable a uniform coating of the substrate 107 surface. Permanent magnets 108 on a magnetic shunt 120 are used to create magnetic confinement fields 101 that extend through the target material 104 and confine the plasma 102 right up against the target material surface 117 with only the dark space 103 that forms from as a function of the target voltage separating the target material surface 117 and the plasma 102.

The target material 104 is typically bonded to a backing material 105 to allow the required water cooling 121 to remove the heat from the sputtering process. The substrate 107 is positioned at a target to substrate distance 106 that provides enough room for the plasma 102 to form sufficiently, allow electrons produced by the ionization process and the secondary electrons produced when sputtering the target material surface 117 to escape from the magnetic confinement fields 101 and return to anode surfaces 110 that can return the electron current to the power supply 109.

The complete the electrical circuit utilizes a power supply 109 to supply electrons to the target material surface 117, create an electric field the repels any free electrons away from the target material surface 117 where they collect in the magnetic confinement fields 101 and can then ionize any process gas that has been supplied into the vacuum chamber 113 by means of a mass flow controller and a gas manifold 112, the ionized process gas forms the plasma 102 and the ions at the bottom edge of the plasma 102 are accelerated across the dark space 103 and come in contact with the target material surface 117 where they are neutralized by electrons supplied by the power supply 109, the ions arriving at the target material surface 117 surface also release secondary electrons.

The electrons from the ionization process in the plasma 102 and the secondary electrons released from the target material surface 117 eventually travel a path of least resistance 115 out of the magnetic confinement fields 101 and along the electric field lines 116 across the inside volume of the vacuum chamber 113 to the anode surfaces 110 where they can return to the power supply 109 and complete the electrical circuit. If the path between the magnetic confinement fields 101 and the anode surface 110 is obstructed the power supply 109 will increase the differential voltage applied between target material surface 117 and the anode surfaces 110 to enable the electrons to find their way to the anode surfaces 110. The magnetic confinement fields 101 is technically an obstruction for the electrons and as the strength of the magnetic field increases when the target material surface 117 is sputtered away the voltage differential usually drops as the strength of the magnetic confinement fields 101 determines how many ions each electron can effectively create before the electron finds its way back to the anode surfaces 110 requiring less electrons to create the plasma and sustain the electrical circuit.

Permanent magnets 108 attached to a magnetic shunt 120 are only so strong so the distance between the surface of the permanent magnets and the target material surface 117 surface to be sputtered must be such that the magnetic field strength measured parallel to the surface of the target material surface 117 must be above 200 to 300 Gauss to sustain a plasma 102 within the magnetic confinement fields 101. This magnetic field strength requirement combined with the need to cool the target material 104 limits the total combined thickness of the target material 104 and the backing material 105. Stray magnetic fields 114 outside of the primary magnetic confinement fields 101 can impede the electron path between the plasma 102 and the anode surface 110 causing the differential voltage to increase and limiting the cross-sectional path the electrons can take between the two surfaces. If any electron path obstructions cause the electron density going through any portion of the vacuum chamber to reach densities near that of those found withing the magnetic confinement fields 101 then spurious plasmas will form in the vacuum chamber 113 that can take energy away from the sputtering process and lead to deposition uniformity issues or contamination of the coating forming on the substrate 107.

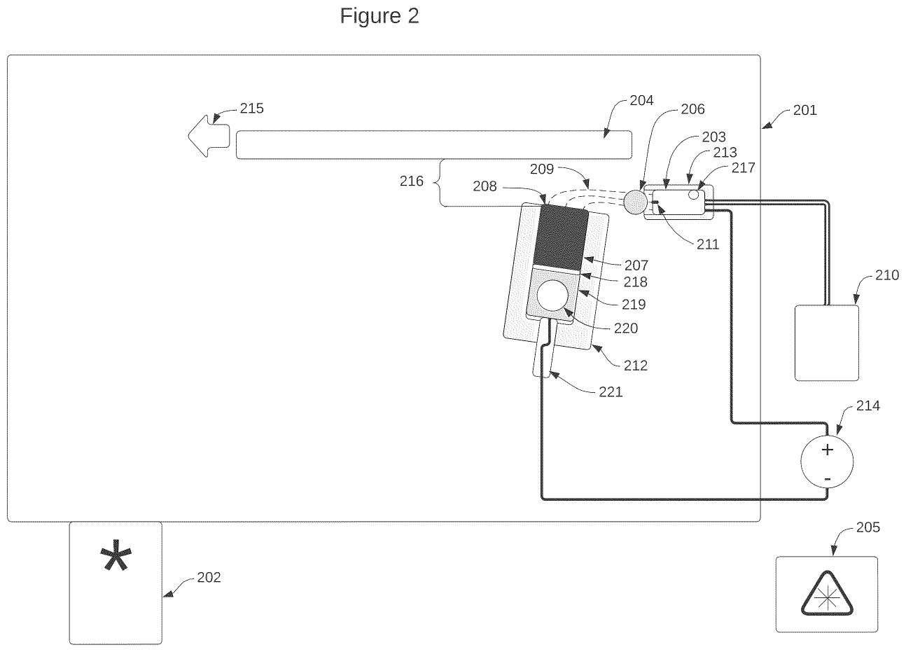

FIG. 2 is an embodiment of the current invention in which a sputtering process inside a vacuum chamber 201 with the same relative dimensions as the chamber from FIG. 1. The vacuum chamber is pumped with a high vacuum pump 202 that is on the opposite side of the sputtering source from the gas manifold 203 to allow all the process gas to travel across the sputtering source. The substrate 204 is traveling through the vacuum system in the same direction 215 as in FIG. 1, but the target to substrate distance 216 is substantially smaller than in FIG. 1. The smaller target to substrate distance 216 enables the long axis of the target material 207 to be very close in length in and out of the plan to the width of the substrate 204 in and out of the plane and still provide a uniform coating.

A laser power supply 205 is used to produce a laser beam that is directed though the plane of FIG. 2 along the long axis of the target material 207 to form a laser ionization zone 206 where the plasma is formed. The plasma in this embodiment is located within an electric field 209 that will accelerate the ion to the target material surface 208. The electric field is produced between the gas manifold 203 and the target material surface 208 using a power supply 214 in a way that the ions arriving at the target surface will have an angle of incidence greater than 0 degrees. The target material surface is not parallel to the substrate 204 to allow the ions accelerated from the plasma in the laser ionization zone 206 to arrive at the target materials surface 208 at an angle of incidence distribution selected as a function of the target material 207 sputter yield properties, electric field 209 strength, electric field 209 shape, process gas pressure, the ion mass, and the ion energy to increase the sputter yield of the ions.

The process gas supplied to the vacuum chamber 201 using a mass flow controller 210 connected directly to a gas manifold 203 that has gas manifold outlets 211 directed right into the laser ionization zone 206. The process gas pressure right at the gas manifold outlets 211 is the highest process gas pressure zone in the entire vacuum system and number of ions produced within the laser ionization zone 206 is a function of the laser power density, laser ionization efficiency, and the process gas species density in the laser ionization zone 206.

Locating the laser ionization zone 206 as close as possible to the gas manifold outlets 211 minimizes the total laser beam power required to generate enough ions to meet sputter rates required for coating the substrate 204. Enclosing all the target material 207 within an insulator or dark space shield 212 except for the target material surface 208 and the similarly enclosing the gas manifold 203 within an insulator or dark space shield 213 enables the electric fields 209 to be shaped in a way to help optimize the angle of incidence of the ions arriving at the target material surface 208. The encapsulation of these elements also enables the electrons produced in the laser ionization zone 206 to be pulled directly into the gas manifold 203 and electrons produced from the secondary electron emission when sputtering target material surface 208 to be pulled through the laser ionization zone 206 into the exposed gas manifold 203 surface.

The electron path between the target material surface 208 and the exposed gas manifold 203 surface helps neutralize the space charge created by the ion traveling from the laser ionization zone 206 to the target material surface 208 while also contributing the ionization of the process gas depending on the strength of the electric fields 209 and the process gas pressure. Depending on the total electron current entering the exposed gas manifold 203 surface the gas manifold 203 may benefit from being water cooled using a gas manifold water cooling channel 217. The target material 207 may also benefit from being cooled depending on the target material 207 properties, sputter yield, and total required sputter rate.

To cool the target material 207, it may be bonded or connected 218 to a cooling block 219 with a water cooling channel 220. The entire target material 207 and attached cooling assembly can be mounted to an actuator 221 used to advance the target material 207 as the target material surface 208 wears away in the sputtering process. The advancement of the target material 207 will keep the target to substrate distance 216 constant during the entire lifetime of the target which keeps the deposition rate and coating uniformity across the substrate 204 constant, a feat not easily achievable with the prior art.

The sputter distribution flux on the substrate 204 across the surface exposed to the sputtering process from the target material surface 208 is a combination of the ion energy and the material dependent sputter yield as a function of the angle of incidence of the ions. While most of the sputter flux will likely be directed normal to the target material surface 208, for most target materials very little sputtered material would reach the exposed gas manifold 203 surface and combined with the smaller mean free path due to the high process gas pressure gradients at the gas manifold outlets 211, the surface of the exposed gas manifold 203 will stay cleaner during the lifetime of the target material 207. The gas manifold 203, laser ionization zone 206, and corresponding target material surface 208 can be resized and or moved to any combination of angles and locations relative to each other to optimize the sputter yield, energy of the sputtered species arriving at the substrate 204 surface, and sputter collection efficiency.

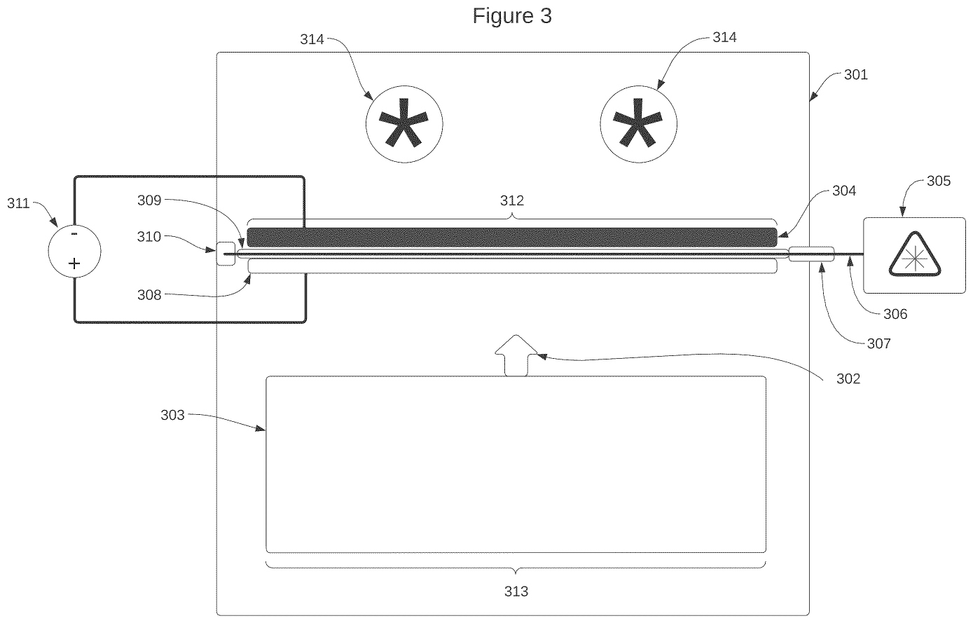

FIG. 3 is a cross section of a vacuum system parallel to the substrate path of motion 302 and the substrate 303. This cross section shows the target material surface 304 below the plane of the substrate 303. A laser generation source 305 is located outside the vacuum chamber 301 and the laser beam 306 is routed through a feedthrough 307 into the vacuum chamber 301 where it passes close near the gas manifold 308 creating a plasma 309 between the gas manifold 308 and the target material surface 304 before being absorbed or reflected at the end of the beam. To accelerate the ions produced in the laser beam 306, a power supply 311 is connected to the target material surface 304 and the gas manifold 308. The target material length 312 is only marginally longer than the width of the substrate 313, as the distance between the target material surface 304 and substrate 303 when the substrate 303 passes over the target material surface 304 can be as small as 25 mm or less while the prior art is typically limited to 75 mm or greater with higher magnetically confined sputtering power densities requiring more 100 mm or more. The process gas introduced into the vacuum chamber 301 from the gas manifold 308 is directed at the laser beam 306 and over the target material surface 304 where it then continues to travel to the vacuum pumps 314.

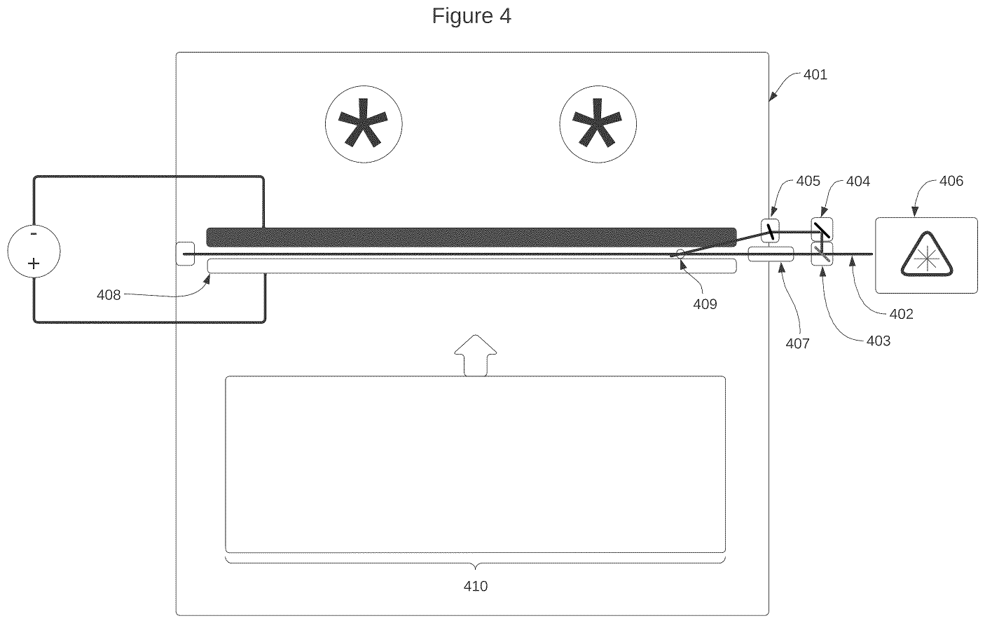

FIG. 4 is the same cross section as FIG. 3 with the laser beam 402 coming out of the laser source 406 and split into two beams with a beam splitter 403 then diverted using a mirror 404 into a laser beam steering optic 405 and feedthrough, then into the vacuum system 401. The laser beam 402 that continues straight through the beam splitter 403 passes through the feedthrough 407 and continues along the gas manifold 408. By splitting the laser beam 402 in half, the total laser beam energy provided by the laser source 406 can be reduced to the point where process gas ionization only occurs at the beam intersection point 409. Not only does this reduce the total required laser beam power but it enables the beam intersection point 409 to be moved anywhere along the gas manifold 408 allowing the scan pattern of the laser beam steering optic 405 to control the deposition profile and coating uniformity across the width of the substrate 410.

Finally, it will be apparent to those skilled in the art that various modifications and variations can be made in the present disclosure without departing from the spirit or scope of the disclosure. Thus, it is intended that the present disclosure cover the modifications and variations of this disclosure provided they come within the scope of the appended claims and their equivalents.

Likewise, numerous characteristics and advantages have been set forth in the preceding description, including various alternatives together with details of the structure and function of the devices and/or methods. The disclosure is intended as illustrative only and as such is not intended to be exhaustive. It will be evident to those skilled in the art that various modifications may be made, especially in matters of structure, deposition materials, elements, components, shape, size and arrangement of parts including combinations within the principles of the invention, to the full extent indicated by the broad, general meaning of the terms in which the appended claims are expressed. To the extent that these various modifications do not depart from the spirit and scope of the appended claims, they are intended to be encompassed therein.

I claim:

1. A sputtering process comprising the steps of:
introducing a process gas into a vacuum chamber with a gas manifold;
ionizing the process gas with a laser to form an ionized process gas;
accelerating the ionized process gas into a target material surface using an actively controlled electric field; and
removing electrons generated by the ionization and sputtering processes with the actively controlled electric field.

2. The sputtering process of claim 1, wherein at least one of a wavelength, power, focus, pulse width and duty cycle of the laser is varied to control the number of ions produced within an ionization zone.

3. The sputtering process of claim 1, wherein at least one of a wavelength, power, focus, pulse width and duty cycle of the laser can be varied to control an ionization level of ions produced within an ionization zone.

4. The sputtering process of claim 1, wherein independent control of an average kinetic energy of ions arriving at the target material surface and an ion flux arriving at the target material surface are used to control a sputter rate.

5. The sputtering process of claim 1, wherein a process gas pressure within an ionization cross-section of the laser limits the number of ions produced by ionization.

6. The sputtering process of claim 1, further comprising multiple laser beams configured to converge to produce a plasma activation spot.

7. The sputtering process of claim 1, wherein a single laser is used to create a line of plasma activation.

8. The sputtering process of claim 1, wherein the laser is scanned relative to the target material surface to maximize target erosion.

9. The sputtering process of claim 1, wherein a laser ionization zone is scanned relative to the target material surface to control coating uniformity deposited onto a substrate.

10. The sputtering process of claim 1, wherein multiple lasers are used to sputter multiple target material surfaces.

11. The sputtering process of claim 1, wherein multiple lasers are used to sputter a single target material surface.

12. The sputtering process of claim 1, wherein the ionized process gas is created in a position relative to the target material surface such that an average kinetic energy of the ionized process gas arriving at the target material surface optimizes a sputter yield.

13. The sputtering process of claim 1, wherein the ionized process gas is created in a position relative to the target material surface such that an angle of incidence of the ionized process gas arriving at the target material surface optimizes a sputter yield.
